(19) United States
(12) Patent Application Publication
(10) Pub. No.: US 2002/0045333 A1
(43) Pub. Date: Apr. 18, 2002

(54) Semiconductor device manufacturing method and semiconductor device

(75) Inventor: Kiyoshi Mori, Tokyo (JP)

Correspondence Address: McDermott, Will & Emery, 600 13th Street, N.W., Washington, DC, 20005-3096, US

(73) Assignee: Mitsubishi Denki Kabushiki Kaisha

(21) Appl. No.: 09/759,323

(22) Filed: Jan. 16, 2001

(30) Foreign Application Priority Data
Jul. 10, 2000 (JP) 2000-208316

(51) Int. Cl. H01L 21/4763

(52) U.S. Cl. 438/618

(57) ABSTRACT

Tungsten wiring 12 is formed on top of a silicon substrate 1. Above the tungsten wiring 12 are formed silicon oxide films 13, 17 and 20; a silicon nitride film 16; or upper electrodes 20 made of a silicon film. Thicknesses of these films are measured on the tungsten wiring 12.

### BACKGROUND OF THE INVENTION

1. Field of the Invention

The present invention relates to a semiconductor device manufacturing method and a semiconductor device. More particularly, the invention relates to a method for manufacturing a semiconductor device having a multilayer insulation film structure and to a semiconductor device manufactured by that method.

2. Description of the Background Art

Semiconductor devices have been required to operate faster and to offer more storage capacity than ever in recent years. The requirements are being met by efforts to fabricate the devices that are finer in structure and of lower resistance than before. Diversifying applications of information processing stimulate the development of system LSIs each combining a semiconductor memory with a logic LSI. Among these system LSIs, one that combines a DRAM with a logic LSI is specifically called an eDRAM (embedded DRAM) designed to effect high-speed processing of mass image data.

With semiconductor devices getting finer in their structures, high degrees of fabrication control are needed to form wiring and contact holes in these structures through individual steps. The need for such advanced control involves frequent uses of silicon nitride films as etching stopper films in the device in order to ensure a significant increase in fabrication margins.

To fabricate finely-structured semiconductor devices at high levels of precision requires accurately managing thicknesses of films that constitute each device. For precise film thickness management, it is necessary accurately to measure thicknesses of interlayer films included in the device. Measurement of interlayer film thicknesses usually involves forming on a silicon substrate an interlayer test pattern that is scrutinized by a measuring instrument. Illustratively, interlayer film thicknesses are measured by an optical apparatus utilizing optical interference for such measurement.

Recently developed system LSIs tend to have a large number of the above-mentioned etching stopper films. This means there are a growing number of interlayer films to be measured in thickness. That is, ever-more thickness test patterns should be provided to measure more interlayer film thicknesses than before.

Film structures that may be handled by optical film thickness measuring instruments are subject to a number of constraints. Typically, if a given film thickness test pattern includes numerous interlayer films, that pattern must be suitably simplified in structure for reasons of measuring expediency. In other words, as more and more layers are included in the semiconductor device, the accuracy of measuring interlayer film thicknesses tends to decline.

### SUMMARY OF THE INVENTION

It is therefore a first object of the present invention to overcome the above and other deficiencies of the prior art and to provide a semiconductor device manufacturing method whereby a large number of interlayer films contained in the device are measured accurately in thickness.

It is a second object of the present invention to provide a semiconductor device that is fabricated by the inventive method above.

The above objects of the present invention are achieved by a method for manufacturing a semiconductor device having a multilayer film structure. In the method, metal wiring is formed on a silicon substrate. At least one functional film is formed on top of the metal wiring. A thickness of the functional film is measured at a position over the metal wiring.

The above objects of the present invention are also achieved by a semiconductor device manufactured by a method described above.

Other objects and further features of the present invention will be apparent from the following detailed description when read in conjunction with the accompanying drawings.

### BRIEF DESCRIPTION OF THE DRAWINGS

FIG. 1 is a cross-sectional view of a semiconductor device fabricated by a method practiced as a first embodiment of this invention;

FIG. 2 is a cross-sectional view of an ordinary film thickness test pattern generally used to measure thicknesses of interlayer films in the semiconductor device of FIG. 1;

FIG. 3 is a cross-sectional view of a typical pattern subject to film thickness measurement by the first embodiment; and

FIG. 4 is across-sectional view of another typical pattern subject to film thickness measurement by the first embodiment.

### DESCRIPTION OF THE PREFERRED EMBODIMENTS

Preferred embodiments of this invention will now be described with reference to the accompanying drawings. Throughout the drawings, like or corresponding parts are designated by the same reference numerals and their descriptions are omitted where redundant.

### First Embodiment

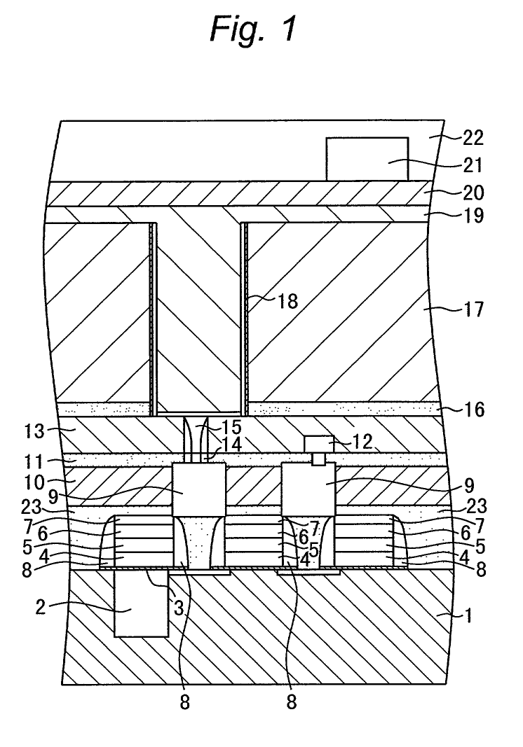

FIG. 1 is a cross-sectional view of a semiconductor device manufactured by a method practiced as the first embodiment of this invention. In FIG. 1, reference numeral 1 denotes a silicon substrate. On the surface of the silicon substrate 1, an isolation region 2 is formed by use off an insulator such as silicon oxide. On top of the silicon substrate 1 are stacked a gate insulation film 3, a polysilicon film 4, a tungsten silicide (WSi) film 5, a silicon oxide film 6, and a silicon nitride film 7, in that order. The polysilicon film 4 and WSi film 5 are covered laterally with side walls 8 for protective purposes, the walls 8 being made of silicon oxide films.

The silicon nitride film 7 is topped with another silicon nitride film 23 which in turn is capped with a silicon oxide film 10. The silicon nitride film 23 and silicon oxide film 10 have contact holes that open onto certain regions (source drain regions) of the silicon substrate 1. Formed inside the contact holes are conductive poly-plugs 9.

On top of the silicon oxide film 10 is formed a silicon nitride film 11. The silicon nitride film 11 is topped with tungsten wiring 12 conducting to the poly-plugs 9. The tungsten wiring 12 is covered with a silicon oxide film 13. The silicon nitride film 11 and silicon oxide film 13 have contact holes that open onto the poly-plugs 9. The contact holes are filled with a silicon nitride film 14 and conductive poly-plugs 15.

The silicon oxide film 13 is capped with a silicon nitride film 16 and a silicon oxide film 17. The silicon nitride film 16 and silicon oxide film 17 have openings that expose upper ends of the poly-plugs 15. The side walls and bottoms of the openings are covered inside with lower electrodes 18 of capacitors. Upper electrode 19 of capacitors are in contact with insulation films (cell plates) which covers the lower electrodes 18 while covering the top of the silicon oxide film 17. The upper electrode 19 is capped with aluminum wiring 21 with a silicon oxide film 20 interposed therebetween. The aluminum wiring 21 is covered with a silicon oxide film 22.

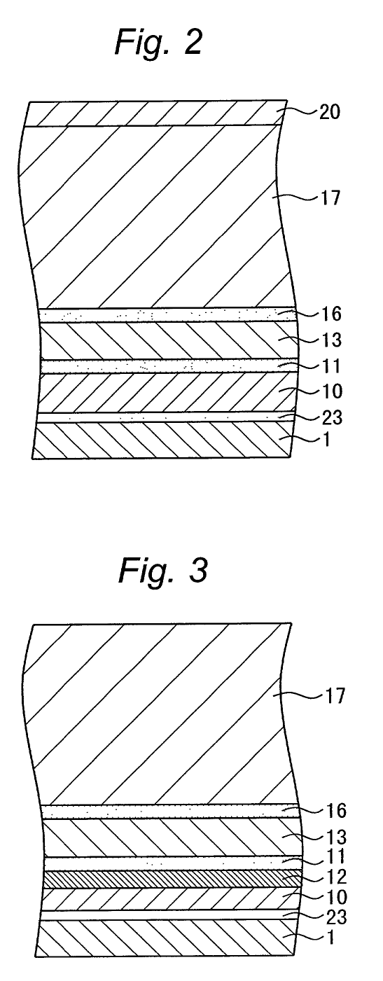

FIG. 2 is a cross-sectional view of a film thickness test pattern formed on the silicon substrate 1 along with the DRAM shown in FIG. 1. If the device fabricated on the silicon substrate 1 has the structure of FIG. 1, then the film thickness test pattern has a multilayer structure comprising the silicon nitride films 23, 11 and 16, as well as the silicon oxide films 10, 13, 17 and 20 as shown in FIG. 2.

With this embodiment, the silicon nitride films 23, 11 and 16 are formed by low-pressure CVD to have thicknesses of 100 angstroms, 100 angstroms and 500 angstroms respectively. The silicon oxide films 10, 13 and 17 are also formed by low-pressure CVD to have thicknesses of 7,000 angstroms, 2,000 angstroms and 17,000 angstroms respectively.

After the film thickness test pattern comprising the above film thicknesses was formed, the inventor measured the pattern for interlayer film thicknesses using an optical film thickness measuring instrument utilizing optical interference. The results showed that the actual measurements were too dispersed on the same plane to be of any use as effective film thickness measurements.

More measuring sessions were conducted with only the silicon nitride film 16 varied in thickness from 0 to 300 to 500 angstroms. It was indicated that the measurements were too dispersed on the same plane to be of any use when the silicon nitride film 16 became thicker than 300 angstroms. The inventor attributed the results to two major phenomena. First, a growing film thickness of the silicon nitride film 16 led to an increase in the total film thickness of the film thickness test pattern, causing a decline in precision of film thickness measurement. Second, when the total film thickness has a great value, it is required to imaginarily simplify the film construction of measuring target for reasons of measuring expediency to adapt to the restrictions on film constitutions that can be addressed by a specific film thickness measuring instrument.

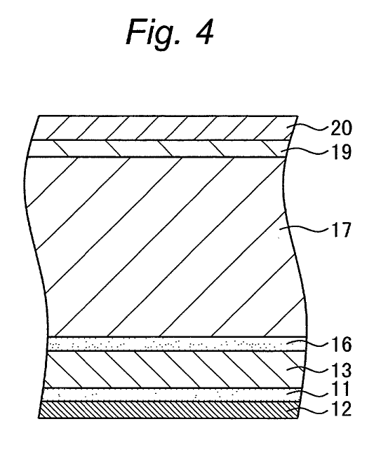

Features of the manufacturing method constituting the first embodiment will now be described by referring to FIGS. 3 and 4. FIG. 3 is a cross-sectional view of a typical pattern subject to film thickness measurement by the first embodiment. Incidentally, the structure shown in FIG. 3 is one which can be obtained at the stage after formation of the silicon nitride film 17 during manufacture of the DRAM in FIG. 1.

As depicted in FIG. 3, the pattern to be measured for film thicknesses by the first embodiment has the tungsten wiring 12 interposed between the silicon oxide film 10 and the silicon nitride film 11. When the inventors measured the pattern using an optical film thickness measuring instrument, adequate measuring results showing few variation in a single plane are obtained.

Where the tungsten wiring 12 exists within a multilayer structure, the optical film thickness measuring instrument can address only the layers above the wiring 12 for film thickness measurement. This means that in the pattern of FIG. 3, the target films to be measured are effectively smaller in thickness and simpler in structure than those in the pattern of FIG. 2. These features were thought to be the reasons why the pattern of FIG. 3 yielded adequate results when measured for film thicknesses.

Although this embodiment has been shown addressing numerous interlayer films deposited on top of the tungsten wiring 12, the beneficial effects of measuring film thicknesses above the wiring 12 are not limited to setups involving the high film count. Alternatively, the embodiment may also be used accurately to measure thicknesses of a small number of films layered on the tungsten wiring 12.

FIG. 4 is a cross-sectional view of another typical pattern subject to film thickness measurement by the first embodiment. The pattern of FIG. 4 has a structure in which the upper electrodes 19 (polysilicon film) and silicon oxide film 20 are layered on top of the pattern in FIG. 3. This structure is obtained after the silicon oxide film 20 has been formed during fabrication of the DRAM shown in FIG. 1.

When the inventor subjected the pattern in FIG. 4 to film thickness measurement using an optical film thickness measuring instrument, the thickness of the silicon oxide film 20 formed on the upper electrodes 19 (polysilicon film) was measured as accurately as any other film. On the other hand, similar measuring sessions conducted on regions where the tungsten wiring 12 did not exist yielded no measurement at all of a thickness of the silicon oxide film 20.

As described, the inventive method of this embodiment effectively simplifies the structure of measuring target which includes metal wiring within a multilayer structure by executing measurement of the same at the position over the metal wiring. That is, the inventive method permits accurate measurement of thicknesses of insulation films and polysilicon films contained in a multilayer structure whereas such films have been difficult to measure conventionally.

Constituted as described above, the present invention offers the following major effects:

A method for manufacturing a semiconductor device according to one aspect of the invention allows a functional film or films to be measured for thickness on top of metal wiring. Because only the functional films above the metal wiring are subject to measurement, the films to be measured constitute a simpler structure than the films measured conventionally above a silicon substrate. This makes it possible accurately to measure thicknesses of the functional films included in the semiconductor device.

One preferred method for manufacturing a semiconductor device according to the invention permits accurate measurement of thicknesses of a silicon nitride film and a silicon oxide film formed on top of the metal wiring.

In another preferred method for manufacturing a semiconductor device according to the invention, a first silicon nitride film and a first silicon oxide film are formed in order to fabricate a lower electrodes of capacitors. Upper electrode of the capacitors is formed using a silicon film on top of the first silicon oxide film. Because thicknesses of the functional films are measured on top of the metal wiring, this method makes it possible to measure thicknesses of not only the silicon nitride film and silicon oxide film but also the upper electrodes composed of the silicon film.

In a further preferred method for manufacturing a semiconductor device according to the invention, a second silicon oxide film is formed on top of the upper electrodes. The thickness of the functional film is measured from above the second silicon oxide film. Because film thicknesses are measured on top of the metal wiring, the target films to be measured for thicknesses constitute a simplified film structure. This makes it possible accurately to measure the thickness of the functional film from above the second silicon oxide film.

An even further preferred method for manufacturing a semiconductor device according to the invention permits accurate film thickness measurement using the metal wiring constituted by tungsten wiring.

Any one of the inventive methods summarized above may be used to manufacture a semiconductor device having functional films whose thicknesses are managed with high precision.

Further, the present invention is not limited to these embodiments, but variations and modifications maybe made without departing from the scope of the present invention.

The entire disclosure of Japanese Patent Application No. 2000-208316 filed on Jul. 10, 2000 including specification, claims, drawings and summary are incorporated herein by reference in its entirety.

What is claimed is

1. A method for manufacturing a semiconductor device having a multilayer film structure, said method comprising the steps of:
forming metal wiring on a silicon substrate;
forming at least one functional film on top of said metal wiring; and
measuring a thickness of said functional film at a position over said metal wiring.

2. The method for manufacturing a semiconductor device according to claim 1, wherein said functional film is a multilayered film made of a silicon nitride film and a silicon oxide film.

3. The method for manufacturing a semiconductor device according to claim 1, further comprising the steps of:
forming a lower electrode of a capacitor on top of said silicon substrate;
forming a first silicon nitride film and a first silicon oxide film surrounding said lower electrode; and
forming an upper electrode of the capacitor using a silicon film on top of said first silicon oxide film;
wherein said functional film includes said upper electrode.

4. The method for manufacturing a semiconductor device according to claim 3, further comprising the step of forming a second silicon oxide film on top of said upper electrode;
wherein the thickness of said functional film is measured from above said second silicon oxide film on top of said metal wiring.

5. The method for manufacturing a semiconductor device according to claim 1, wherein said metal wiring is constituted by tungsten wiring.

6. A semiconductor device manufactured by a method according to claim 1.
